(19) United States
(12) Patent Application Publication
(10) Pub. No.: US 2013/0088247 A1
(43) Pub. Date: Apr. 11, 2013

(54) READOUT APPARATUS AND READOUT METHOD FOR SENSOR ARRAY

(71) Applicants: Kuo-Hua Tseng, New Taipei City (TW); Chang-Ho Liou, Changhua County (TW); Yan-Rung Lin, Hsinchu City (TW); Kuan-Wei Chen, Taichung City (TW)

(72) Inventors: Kuo-Hua Tseng, New Taipei City (TW); Chang-Ho Liou, Changhua County (TW); Yan-Rung Lin, Hsinchu City (TW); Kuan-Wei Chen, Taichung City (TW)

(73) Assignee: INDUSTRIAL TECHNOLOGY RESEARCH INSTITUTE, Hsinchu (TW)

(21) Appl. No.: 13/311,551

(22) Filed: Dec. 6, 2011

(30) Foreign Application Priority Data
Oct. 5, 2011 (TW) 100136114

(51) Int. Cl. G01R 27/08

(52) U.S. Cl. 324/693

(57) ABSTRACT

A readout apparatus and a readout method for a sensor array are provided. The readout apparatus includes a switching circuit, a control unit, a gain circuit and an offset compensating circuit. The control unit controls the switching circuit to perform a switching operation for selecting a target sensor from a plurality of sensors of the sensor array. The gain circuit selectively senses the target sensor according the switching operation of the switching circuit, and gains the sensing result to output a gained sensing value of the target sensor. The control unit further dynamically decides a compensating value according the switching operation. The offset compensating circuit adjusts the gained sensing value for outputting a compensated sensing value of the target sensor in accordance with the compensating value.

### CROSS-REFERENCE TO RELATED APPLICATION

This application claims the priority benefit of Taiwan application serial no. 100136114, filed on Oct. 5, 2011. The entirety of the above-mentioned patent application is hereby incorporated by reference herein and made a part of this specification.

### BACKGROUND OF THE DISCLOSURE

1. Field of the Disclosure

The disclosure relates to an electronic product having a pressure sensor array. Particularly, the disclosure relates to a readout apparatus and a readout method for a sensor array.

2. Description of Related Art

Some electronic products are equipped with a sensor array. For example, a nurse mattress is equipped with a pressure sensor array to detect/record a sleep lying state of a user/patient. Therefore, a flexible electronic component technology is developed. The sensor array formed by variable resistance pressure sensors has features of simple structure, easy usage, lightweight, flexibility, drop resistance and low power consumption, etc., and can be fabricated through a printing technique.

However, initial resistances (resistances of a pressure free state) of a plurality of pressure sensors in the variable resistance pressure sensor array are probably different due to variable factors of a fabrication process, and/or response gains of the pressure sensors are different. The different initial resistances and different response gains of the pressure sensors may cause measurement errors and a problem in array measurement uniformity. For example, a following table 1 lists sensing values of a plurality of variable resistance pressure sensors of a 3×3 sensor array in a non-load state (the pressure free state). According to the table 1, it is known that the resistances of the nine pressure sensors of the 3×3 sensor array measured under the non-load state are between 122 KΩ and 342 KΩ. The errors of the initial resistances of different pressure sensors are between dozens of KΩ and hundreds of KΩ.

TABLE 1
sensing values of 3 × 3 sensor array in non-load state

| | First column | Second column | Third column |
|---|---|---|---|
| First row | 342000 Ω | 260000 Ω | 160000 Ω |
| Second row | 166000 Ω | 122000 Ω | 188000 Ω |
| Third row | 230000 Ω | 130000 Ω | 156000 Ω |

Moreover, the different response gains of the pressure sensors may also cause the problem in array measurement uniformity of the sensors. For example, a following table 2 lists differences of sensing values of a plurality of variable resistance pressure sensors of a 3×3 sensor array under pressure functions of a 200 g weight and a 500 g weight. According to experiment data of the table 2, it is known that the nine pressure sensors of the 3×3 sensor array has different response values under the pressure functions of the 500 g weight and the 200 g weight. In case of the same pressure variation, the response gains of the different pressure sensors are different, which may cause measurement errors and the problem in array measurement uniformity.

TABLE 2
differences of sensing values of 3 × 3 sensor array under 500 g
pressure and 200 g pressure

| | First column | Second column | Third column |
|---|---|---|---|
| First row | 13500 Ω | 31300 Ω | 10000 Ω |
| Second row | 14200 Ω | 7500 Ω | 11300 Ω |
| Third row | 7100 Ω | 11000 Ω | 17600 Ω |

### SUMMARY OF THE DISCLOSURE

The disclosure is directed to a readout apparatus and a readout method for a sensor array, by which a zero point offset (for example, offset of an initial resistance) is compensated, and/or a response gain is compensated, so as to reduce influence on a system module caused by fabrication process variation of the pressure sensors or material error.

An embodiment of the disclosure provides a readout apparatus for a sensor array, which includes a switching circuit, a control unit, a gain circuit and an offset compensating circuit. The switching circuit is coupled to the sensor array. The control unit is coupled to the switching circuit, and controls the switching circuit to perform a switching operation for selecting a target sensor from a plurality of sensors of the sensor array. The gain circuit selectively senses the target sensor in the sensors according the switching operation of the switching circuit, and gains a sensing result to output as a gained sensing value of the target sensor. The control unit further dynamically determines a compensating value according the switching operation. The offset compensating circuit is coupled to the gain circuit for receiving the gained sensing value, and adjusts the gained sensing value according to the compensating value to output as a compensated sensing value of the target sensor.

An embodiment of the disclosure provides a readout method for a sensor array, which includes following steps. A switching operation is performed to select a target sensor from a plurality of sensors of the sensor array. A compensating value is dynamically determined according to the switching operation. The target sensor in the sensors is selectively sensed according the switching operation, and a sensing result is gained to serve as a gained sensing value of the target sensor. The gained sensing value is adjusted according to the compensating value to serve as a compensated sensing value of the target sensor.

An embodiment of the disclosure provides a readout apparatus for a sensor array, which includes a switching circuit, a control unit and a gain circuit. The switching circuit is coupled to the sensor array. The control unit is coupled to the switching circuit, and controls the switching circuit to perform a switching operation for selecting a target sensor from a plurality of sensors of the sensor array. The control unit dynamically determines a gain value according the switching operation. The gain circuit selectively senses the target sensor in the sensors according the switching operation of the switching circuit, and gains a sensing result according to the gain value to output as a gained sensing value of the target sensor.

An embodiment of the disclosure provides a readout method for a sensor array, which includes following steps. A switching operation is performed to select a target sensor from a plurality of sensors of the sensor array. A gain value is dynamically determined according to the switching operation. The target sensor in the sensors is selectively sensed according the switching operation to obtain a sensing result. The sensing result is gained according to the gain value to serve as a gained sensing value of the target sensor.

According to the above descriptions, in the disclosure, different compensating values are dynamically determined according to zero point offsets (for example, offsets of initial resistances) of different sensors, and zero point offset compensation is performed to the sensor according to the corresponding compensating value. Moreover, different gain values are dynamically determined according to response gains of different sensors, and then gain adjustment is performed on the sensing result according to the corresponding gain value. Therefore, the readout apparatus and the readout method of the disclosure can reduce influences caused by fabrication process variation of the sensors or material error.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a functional block schematic diagram of a sensing device according to an embodiment of the disclosure.

FIG. 2 is a functional block schematic diagram of a readout apparatus of a sensor array of FIG. 1 according to an embodiment of the disclosure.

FIG. 3 is a functional block schematic diagram of an offset compensating circuit of FIG. 2 according to an embodiment of the disclosure.

FIG. 4 is a schematic diagram of a converting circuit of a compensating value V2 of FIG. 3 according to another embodiment of the disclosure.

FIG. 5 is a functional block schematic diagram of a readout apparatus of a sensor array of FIG. 1 according to another embodiment of the disclosure.

FIG. 6 is a circuit schematic diagram of a gain circuit of FIG. 5 according to an embodiment of the disclosure.

FIG. 7 is a circuit schematic diagram of the gain circuit of FIG. 5 according to another embodiment of the disclosure.

FIG. 8 is a functional block schematic diagram of a readout apparatus of a sensor array of FIG. 1 according to another embodiment of the disclosure.

### DETAILED DESCRIPTION OF DISCLOSED EMBODIMENTS

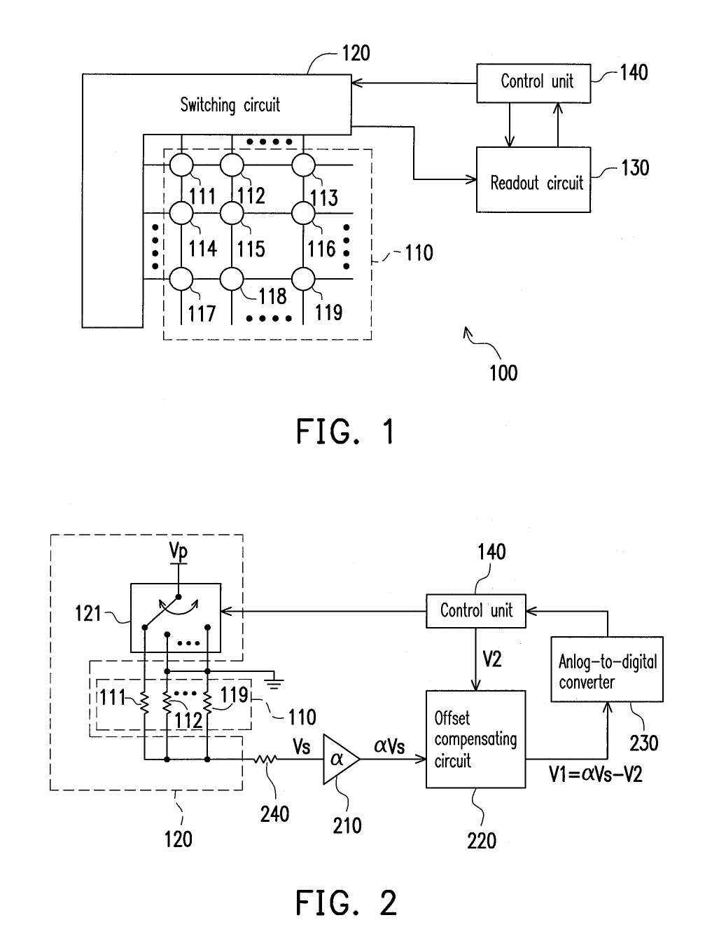

FIG. 1 is a functional block schematic diagram of a sensing device 100 according to an embodiment of the disclosure. The sensing device 100 includes a sensor array 110 and a readout apparatus. The readout apparatus includes a switching circuit 120, a readout circuit 130 and a control unit 140. The sensor array 110 includes a plurality of sensors, for example, the sensors 111, 112, 113, 114, 115, 116, 117, 118 and 119, etc. shown in FIG. 1. The referential numbers 111-119 of FIG. 1 are not used to represent/limit the number of the sensors in the sensor array 110. Those skilled in the art can deduce sensor arrays of other layout structures and sensor numbers according to the instruction of the present embodiment.

The control unit 140 is coupled to the switching circuit 120 and the readout circuit 130. The control unit 140 controls the switching circuit 120 to perform a switching operation for selecting a target sensor from the sensors 111-119 of the sensor array 110. The readout circuit 130 reads a sensing value of the target sensor according to the switching operation of the switching circuit 120, and transmits the sensing value to the control unit 140.

FIG. 2 is a functional block schematic diagram of the readout apparatus of the sensor array of FIG. 1 according to an embodiment of the disclosure. Related descriptions of FIG. 1 are referred for the embodiment of FIG. 2, the readout apparatus includes the switching circuit 120, the readout circuit 130 and the control unit 140. The readout circuit 130 includes a gain circuit 210 and an offset compensating circuit 220.

For simplicity's sake, the sensors 111-119 are variable resistance pressure sensors, so that the sensors 111-119 are illustrated in resistor symbols in FIG. 2. When the sensor is subjected to an external pressure, a resistance of the sensor varies as the pressure varies. The switching circuit 120 is coupled to the sensor array 110 and the control unit 140. The control unit 140 controls the switching circuit 120 to perform the switching operation to select the target sensor from the sensors 111-119 of the sensor array 110. For example, when the control unit 140 controls a switch 121 of the switching circuit 120 to switch a bias voltage Vp to the sensor 111, the switching circuit 120 couples a reference voltage lower than the bias voltage Vp to the other sensors 112-119 other than the target sensor 111 (as that shown in FIG. 2), which is equivalent to that the switching circuit 120 performs the switching operation to select the sensor 111 from the sensors 111-119 of the sensor array 110 to serve as the target sensor. The reference voltage can be a ground voltage or a system lowest voltage. For another example, when the control unit 140 controls the switch 121 to switch the bias voltage Vp to the sensor 112, the switching circuit 120 couples the reference voltage (for example, the ground voltage) to the other sensors (for example, the sensor 111, the sensor 119, etc.) other than the target sensor 112. The switch 121 in the switching circuit 120 of FIG. 2 is only an example, and any sensor array switching mechanism/means known by those skilled in the art can be used to implement the switching circuit 120.

An overload protection resistor 240 is illustrated in FIG. 2. The overload protection resistor 240 is connected in series between the target sensor and the gain circuit 210, i.e. connected in series between the sensor array 110 and the gain circuit 210. When one of the pressure sensors 111-119 is subjected to an excessive pressure, the resistance of the sensor approaches to a short-circuit resistance (i.e. approaches to 0), and now regardless of whether the switching circuit 120 drives the sensor array 110 in a constant current bias manner (not shown) or a constant voltage manner (shown in FIG. 2), the sensor of the sensors 111-119 that is subjected to the excessive pressure probably generate an excessive current or an excessive voltage, which may cause a false operation of the system. The overload protection resistor 240 can be used to reduce a current or voltage impact on the gain circuit 210. In other embodiments, if a maximum current or maximum voltage produced by the sensors 111-119 is tolerable to the system, or if the pressure sensors 111-119 do not approach to the short-circuit resistance regardless of how great the pressure is, the overload protection resistor 240 can be omitted.

In other embodiments, the readout apparatus of the sensor array 110 can also include a thermal resistor (not shown). The thermal resistor is connected in parallel to the overload protection resistor 240 and is connected in series between the sensor array 110 and the gain circuit 210. Alternatively, the thermal resistor and the overload protection resistor 240 are connected in series between the sensor array 110 and the gain circuit 210. If the sensors 111-119 are resistors having positive temperature coefficients, the thermal resistor has a negative temperature coefficient. Conversely, if the sensors 111-119 are resistors having negative temperature coefficients, the thermal resistor has a positive temperature coefficient.

In a different embodiment, the overload protection resistor 240 itself can be a thermal resistor. For example, if the sensors 111-119 are resistors having positive temperature coefficients, the overload protection resistor 240 has a negative temperature coefficient. Conversely, if the sensors 111-119 are resistors having negative temperature coefficients, the overload protection resistor 240 has a positive temperature coefficient.

Referring to FIG. 2, it is assumed that the switching circuit 120 selects the sensor 111 of the sensors 111-119 to serve as the target sensor under control of the control unit 140, one end of the target sensor 111 receives the bias voltage Vp, and another end of the target sensor 111 outputs a sensing result Vs through the overload protection resistor 240. The gain circuit 210 selectively senses the target sensor 111 according the switching operation of the switching circuit 120, and gains (for example, a gain value of a) the sensing result Vs to output as a gained sensing value of the target sensor 111, i.e. outputs a gained sensing value α×Vs to the offset compensating circuit 220.

The control unit 140 dynamically determines a compensating value V2 according the switching operation. According to an application requirement, the compensating value V2 output to the offset compensating circuit 220 by the control unit 140 can be a digital type or an analog type. The compensating value V2 is determined by the control unit 140 according to sensing values (or initial resistance values) of the sensors 111-119 of the sensor array 110 in a non-load state (a pressure free state). The control unit 140 may have a look-up table to record different compensating values corresponding to the sensors 111-119. According to the switching operation of the switching circuit 120, the control unit 140 obtain the compensating value V2 corresponding to the target sensor 111 from the look-up table. In the present embodiment, if the sensor array 111 includes m sensors, the look-up table correspondingly records m compensating values in a one-to-one manner. A method of establishing the look-up table includes following steps. The sensors 111-119 are kept in the non-load state. The sensors 111-119 in the non-load state are sensed to obtain non-load sensing values of the sensors 111-119. Then, the non-load sensing values are taken as the compensating values corresponding to the sensors 111-119, and the compensating values are recorded in the look-up table.

In other embodiments, the sensors 111-119 are grouped into different groups according to the sensing values (or the initial resistance values) thereof in the non-load state (the pressure free state), the look-up table is only required to record the compensating value corresponding to each of the groups. A method of establishing the look-up table includes following steps. The sensors 111-119 are kept in the non-load state. The sensors 111-119 in the non-load state are sensed to obtain non-load sensing values of the sensors 111-119. The non-load sensing values are grouped into a plurality of groups according to magnitudes thereof, where each group has a compensating value. Then, the compensating values corresponding to the non-load sensing values are recorded in the look-up table.

The offset compensating circuit 220 is coupled to the gain circuit 210 and the control unit 140. The offset compensating circuit 220 receives the gained sensing value α×Vs output by the gain circuit 210, and adjusts the gained sensing value α×Vs according to compensating value V2 determined by the control unit 140, and outputs the adjusted gained sensing value α×Vs to serve as a compensated sensing value V1 of the target sensor (for example, the sensor 111). For example, compensated sensing value V1 output by the offset compensating circuit 220 is α×Vs−V2.

Any means can be used to implement the offset compensating circuit 220 according to the instructions of the present embodiment. For example, the offset compensating circuit 220 can be an error amplifier. An inverting input terminal of the error amplifier receives the compensating value V2, a non-inverting input terminal of the error amplifier is coupled to the gain circuit 210 to receive the gained sensing value α×Vs, and an output terminal of the error amplifier outputs the compensated sensing value V1. For another example, the offset compensating circuit 220 can be a subtracter. The subtracter receives the gained sensing value α×Vs and the compensating value V2 and calculates a difference there between, and outputs the difference to serve as the compensated sensing value V1 of the target sensor (for example, the sensor 111).

In the present embodiment, since different compensating values V2 can be dynamically determined according to zero point offsets (for example, initial resistance value offsets) of different sensors 111-119, and then zero point offset compensation is performed to the sensor according to the corresponding compensating value, the readout apparatus of the embodiment can mitigate influences on the sensors 111-119 caused by fabrication process variation or material error.

In the present embodiment, the compensated sensing value V1 output by the offset compensating circuit 220 is an analog signal, and the input signal of the control unit 140 is a digital signal, so that the readout apparatus of the sensor array 110 further has an analog-to-digital converter (ADC) 230. The ADC 230 is coupled between the offset compensating circuit 220 and the control unit 140. The ADC 230 converts the analog compensated sensing value V1 into a digital form, and transmits the digital compensated sensing value V1 to the control unit 140. In other embodiments, if the compensated sensing value V1 output by the offset compensating circuit 220 is a digital signal, or the control unit 140 can directly receive/process the analog compensated sensing value V1, the ADC 230 can be omitted.

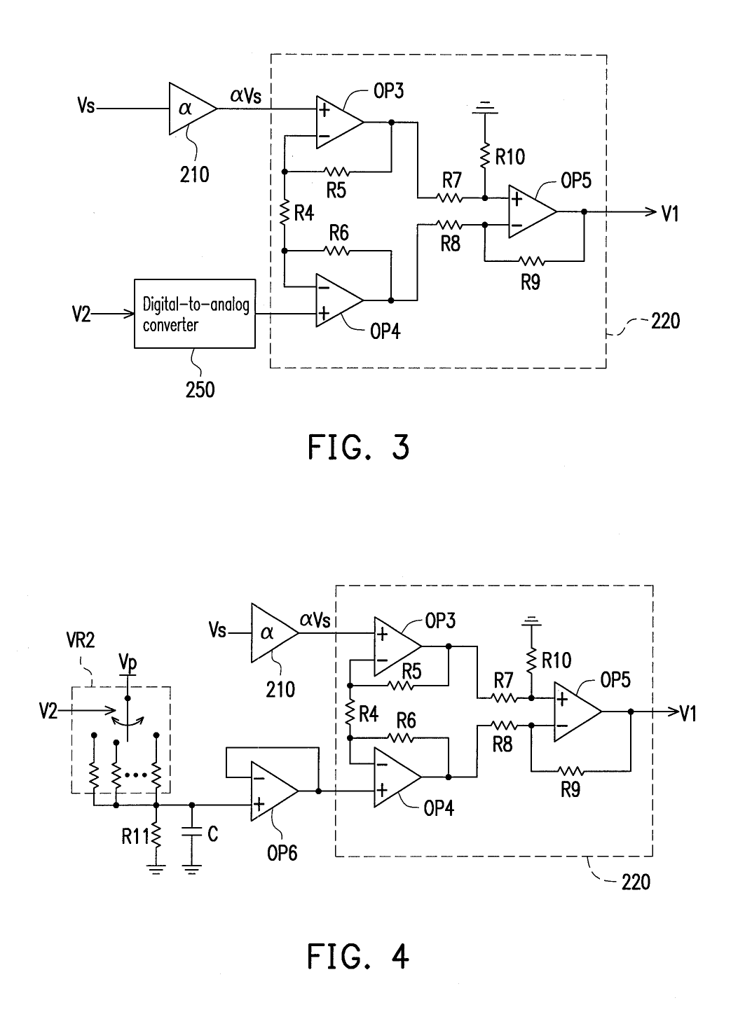

FIG. 3 is a functional block schematic diagram of the offset compensating circuit 220 of FIG. 2 according to an embodiment of the disclosure. The embodiment of FIG. 3 can refer to related descriptions of FIG. 1 and FIG. 2. The embodiment of FIG. 3 further includes a digital-to-analog converter (DAC) 250. The DAC 250 dynamically outputs an analog compensating value to the offset compensating circuit 220 under control of the control unit 140. For example, the DC 250 converts the digital compensating value V2 into an analog voltage, and outputs the analog voltage to the offset compensating circuit 220. In other embodiments, if the compensating value V2 output by the control unit 140 is an analog voltage, the DAC 250 can be omitted.

The offset compensating circuit 220 includes a third amplifier OP3, a fourth amplifier OP4, a fifth amplifier OP5, a fourth resistor R4, a fifth resistor R5, a sixth resistor R6, a seventh resistor R7, an eighth resistor R8, a ninth resistor R9 and a tenth resistor R10. A non-inverting input terminal of the third amplifier OP3 is coupled to the gain circuit 210 for receiving the gained sensing value α×Vs. A non-inverting input terminal of the fourth amplifier OP3 receives the compensating value V2 through the DAC 250. A first end and a second end of the four resistor R4 are respectively coupled to an inverting input terminal of the third amplifier OP3 and an inverting input terminal of the fourth amplifier OP4. A first end and a second end of the fifth resistor R5 are respectively coupled to the inverting input terminal and an output terminal of the third amplifier OP3. A first end and a second end of the sixth resistor R6 are respectively coupled to the inverting input terminal and an output terminal of the fourth amplifier OP4. A first end of the seventh resistor R7 is coupled to the output terminal of the third amplifier OP3. A first end of the eighth resistor R8 is coupled to the output terminal of the fourth amplifier OP4. A non-inverting input terminal of the fifth amplifier OP5 is coupled to a second end of the seventh resistor R7, an inverting input terminal of the fifth amplifier OP5 is coupled to a second end of the eighth resistor R8, and an output terminal of the fifth amplifier OP5 outputs the compensated sensing value V1. A first end and a second end of the ninth resistor R9 are respectively coupled to the inverting input terminal and the output terminal of the fifth amplifier OP5. A first end of the tenth resistor R10 is coupled to the non-inverting input terminal of the fifth amplifier OP5, and a second end of the tenth resistor R10 is coupled to the reference voltage (for example, the ground voltage or other fixed voltages).

The DAC 250 of FIG. 3 is not used to limit the disclosure, and those skilled in the art can use any means to replace the DAC 250 according to the instructions of the aforementioned embodiment. For example, FIG. 4 is a schematic diagram of a converting circuit of the compensating value V2 of FIG. 3 according to another embodiment of the disclosure. The embodiment of FIG. 4 can refer to related descriptions of FIG. 3. Referring to FIG. 4, the readout apparatus of the sensor array further includes a second variable resistance unit VR2, a eleventh resistor R11 and a sixth amplifier OP6. A first end of the second variable resistance unit VR2 is coupled to the bias voltage Vp. A resistance of the second variable resistance unit VR2 is varied under control of the control unit 140. In the present embodiment, the second variable resistance unit VR2 includes a switch and a plurality of resistors having different resistances. The switch is controlled by the compensating value V2 of the control unit 140. The switch selects to couple the bias voltage Vp to one of the resistors according to the compensating value V2. Therefore, the resistance of the second variable resistance unit VR2 is varied under control of the control unit 140.

A first end of the eleventh resistor R11 is coupled to a second end of the second variable resistance unit VR2, a second end of the eleventh resistor R11 is coupled to the reference voltage (for example, the ground voltage or other fixed voltages). A non-inverting input terminal of the sixth amplifier OP6 is coupled to the second end of the second end of the second variable resistance unit VR2, an inverting input terminal of the sixth amplifier OP6 is coupled to an output terminal of the sixth amplifier OP6, and the output terminal of the sixth amplifier OP6 outputs a compensating value to the offset compensating circuit 220. In the embodiment, the non-inverting input terminal of the sixth amplifier OP6 is further coupled to a first end of a capacitor C, and a second end of the capacitor C is coupled to the ground, where the capacitor C is used to filter noises.

In the present embodiment, if the sensor array 110 includes m sensors, the number of the resistors in the second variable resistance unit VR2 is m, namely, the resistors in the second variable resistance unit VR2 corresponds to the sensors in the sensor array 110 in a one-to-one manner. Therefore, by dividing the bias voltage Vp through the second variable resistance unit VR2 and the eleventh resistor R11, different compensating voltages corresponding to different sensors in the sensing array 110 are generated for the offset compensating circuit 220.

In other embodiments, the sensors 111-119 are grouped into different groups according to the sensing values (or the initial resistance values) thereof in the non-load state (the pressure free state), so that the number of the resistors in the second variable resistance unit VR2 is only required to match a group number of the sensors 111-119. For example, when the sensors 111-119 are grouped into three groups, the second variable resistance unit VR2 is only required to have at least three resistors. Therefore, by using the second variable resistance unit VR2 and the eleventh resistor R11 to divide the bias voltage Vp, different compensating voltages corresponding to different groups of the sensors 111-119 are generated for the offset compensating circuit 220.

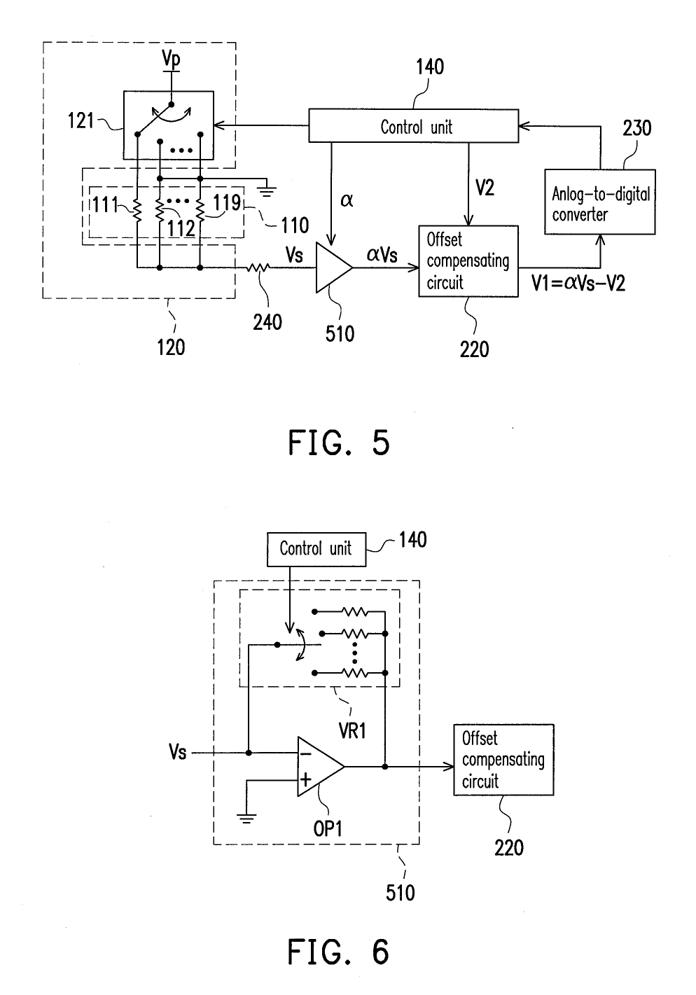

FIG. 5 is a functional block schematic diagram of a readout apparatus of a sensor array of FIG. 1 according to another embodiment of the disclosure. The embodiment of FIG. 5 can refer to related descriptions of FIG. 2, FIG. 3 and FIG. 4. Different to the embodiment of FIG. 2, in the embodiment of FIG. 5, a gain circuit 510 dynamically determine the gain value α under control of the control unit 140. Referring to FIG. 5, the control unit 140 dynamically determines the corresponding gain value α according to the switching operation of the switching circuit 120. The gain circuit 510 gains the sensing result Vs according to the gain value α to obtain the gained sensing value α×Vs of a certain target sensor in the sensors 111-119.

In the present embodiment, the control unit 140 has a look-up table to record different gain values corresponding to the sensors 111-119. The control unit 140 obtain the gain value α corresponding to the target sensor from the look-up table according to the switching operation of the switching circuit 120. In the present embodiment, if the sensor array 111 includes m sensors, the look-up table correspondingly records m gain values in a one-to-one manner. A method of establishing the look-up table includes following steps. The sensors 111-119 are kept in a first load state, and the sensors 111-119 in the first load state are sensed to obtain first load sensing values of the sensors 111-119. Further, the sensors 111-119 are kept in a second load state, and the sensors 111-119 in the second load state are sensed to obtain second load sensing values of the sensors 111-119. Slopes of load-sensing value characteristic curves of the sensors 111-119 are calculated according to the first load sensing values and the second load sensing values. Then, the slopes are taken as different gain values corresponding to the sensors 111-119, and the gain values are recorded in the look-up table.

In other embodiments, the sensors 111-119 are grouped into a plurality of groups according to the slopes of load-sensing value characteristic curves, so that the look-up table is only required to record a different gain value corresponding to each of the groups. A method of establishing the look-up table includes following steps. The sensors 111-119 are kept in a first load state, and the sensors 111-119 in the first load state are sensed to obtain first load sensing values of the sensors 111-119. Further, the sensors 111-119 are kept in a second load state, and the sensors 111-119 in the second load state are sensed to obtain second load sensing values of the sensors 111-119. Slopes of load-sensing value characteristic curves of the sensors 111-119 are calculated according to the first load sensing values and the second load sensing values. The slopes are grouped into a plurality of groups according to magnitudes thereof, where each group has a gain value. Then, the gain values corresponding to the slopes are recorded in the look-up table.

In the embodiment, since different gain values α are dynamically determined according to response gains of different sensors, and then gain adjustment is performed on the sensing result Vs according to the corresponding gain value α, the readout apparatus of the embodiment can mitigate the influence on the sensors 111-119 caused by fabrication process variation or material error.

FIG. 6 is a circuit schematic diagram of the gain circuit 510 of FIG. 5 according to an embodiment of the disclosure. The gain circuit 510 includes a first amplifier OP1 and a first variable resistance unit VR1. A non-inverting input terminal of the first amplifier OP1 is coupled to the reference voltage (for example, the ground voltage or other fixed voltages), and an inverting input terminal of the first amplifier OP1 is selectively coupled to a certain target sensor in the sensors 111-119 according to the switching operation of the switching circuit 120. A first end and a second end of the first variable resistance unit VR1 are respectively coupled to the inverting input terminal and an output terminal of the first amplifier OP1. The first variable resistance unit VR1 is controlled by the control unit 140, and a resistance of the first variable resistance unit VR1 is varied along with the switching operation of the switching circuit 120. In the present embodiment, the first variable resistance unit VR1 includes a plurality of first resistors and a first switch. Resistances of the first resistors are different. First ends of the first resistors are commonly coupled to the output terminal of the first amplifier OP1. The first switch selectively couple the inverting input terminal of the first amplifier OP1 to a second end of one of the first resistors according to the switching operation of the switching circuit 120, as that shown in FIG. 6.

In the present embodiment, if the sensor array 110 includes m sensors, the number of the first resistors in the first variable resistance unit VR1 is m, namely, the first resistors in the first variable resistance unit VR1 corresponds to the sensors in the sensor array 110 in a one-to-one manner. Therefore, by dynamically adjusting the resistance of the first variable resistance unit VR1, the gain circuit 510 can generate different gain values α corresponding to different sensors in the sensing array 110.

In other embodiments, the sensors 111-119 are grouped into a plurality of groups according to magnitudes of the slopes of the load-sensing value characteristic curves, so that the number of the first resistors in the first variable resistance unit VR1 is only required to match a group number of the sensors 111-119. For example, when the sensors 111-119 are grouped into three groups, the first variable resistance unit VR1 is only required to have at least three first resistors. Therefore, by dynamically adjusting the resistance of the first variable resistance unit VR1, the gain circuit 510 generates different gain values α corresponding to different groups of the sensors 111-119.

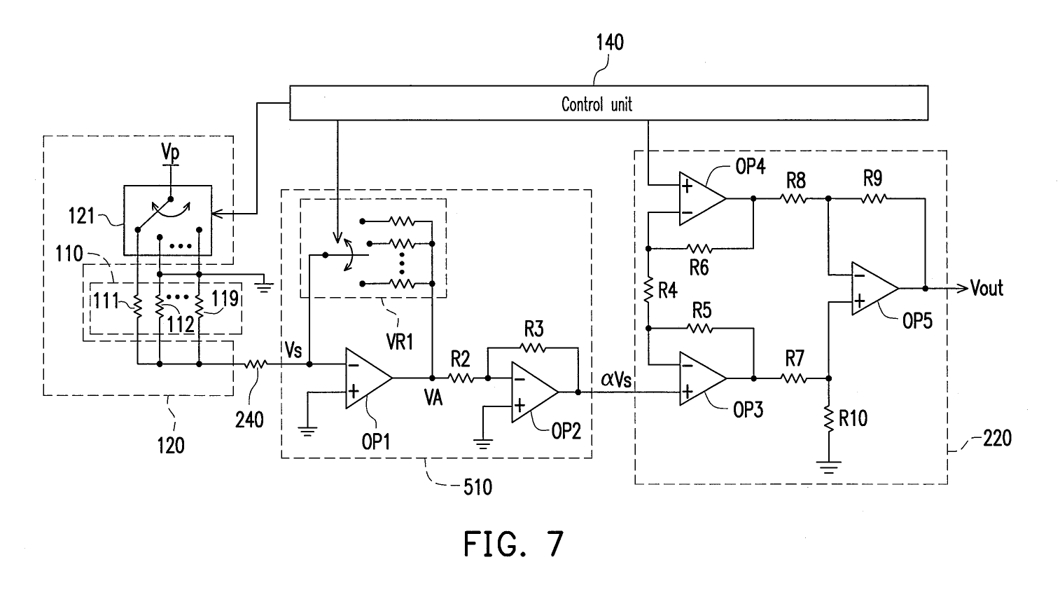

FIG. 7 is a circuit schematic diagram of the gain circuit 510 of FIG. 5 according to another embodiment of the disclosure. The embodiment of FIG. 7 can refer to related descriptions of FIG. 3, FIG. 4, FIG. 5 and FIG. 6. Different to the embodiment of FIG. 6, in the embodiment of FIG. 7, the gain circuit 510 further includes a second amplifier OP2, a second resistor R2 and a third resistor R3. A non-inverting input terminal of the second amplifier OP2 is coupled to the reference voltage (for example, the ground voltage or the other fixed voltages). A first end and a second end of the second resistor R2 are respectively coupled to the output terminal of the first amplifier OP1 and an inverting input terminal of the second amplifier OP2. A first end and a second end of the third resistor R3 are respectively coupled to the inverting input terminal of the second amplifier OP2 and an output terminal of the second amplifier OP2. The output terminal of the second amplifier OP2 supplies the gained sensing value to α×Vs to the offset compensating circuit 220. In the embodiment of FIG. 7, it is assumed that a gain value of the first amplifier OP1 is α1, and a gain value of the second amplifier OP2 is α2, the gain value α of the gain circuit 510 is α1×α2.

When a resistance of the target sensor in the sensors 111-119 is Rs, and a resistance of the overload protection resistor 240 is R0, the sensing result Vs is Vp/(Rs+R0). An output VA of the first amplifier OP1 is −VR1×Vs. An output α×Vs of the second amplifier OP2 is VR1×Vs×(R3/R2), i.e. the gain value α of the gain circuit 510 is (VR1×R3)/R2. By controlling the resistance of the variable resistance unit VR1, the gain circuit 510 dynamically determines different gain values α, so as to perform gain adjustments on the sensing results Vs of different sensors 111-110, and compensate the slopes of the load-sensing value characteristic curves of different sensors.

By analysing the offset compensating circuit 220 of FIG. 7, the output of the offset compensating circuit 220 is Vout={(R9×R6)/(R8×R4)+[1+(R9/R8)]×[R10/(R7+R10)]×[1+(R5/R4)]}×(α×Vs)−{(R9/R8)×[(R6×R9)/(R4×R8)]+[1+(R9/R8)]×[R10/(R7+R10)]×[R5/R4]}×V2. Therefore, by dynamically determining different compensating values V2, the offset compensating circuit 220 can dynamically perform zero point offset compensation on zero point offset (for example, offset of a initial resistance) of different sensors 111-119.

According to the above descriptions, a readout method for a sensor array is described below, which includes following steps. A switching operation is performed to select a target sensor from a plurality of sensors of the sensor array. The target sensor in the sensors is selectively sensed according the switching operation, and a sensing result is gained to serve as a gained sensing value of the target sensor. A compensating value is dynamically determined according to the switching operation. The gained sensing value is adjusted according to the compensating value to serve as a compensated sensing value of the target sensor.

In an embodiment, the step of dynamically determining the compensating value includes recording different compensating values corresponding to the sensors into a look-up table; and getting the compensating value of the target sensor from the look-up table according to the switching operation. The step of adjusting the gained sensing value includes calculating a difference between the gained sensing value and the compensating value; and outputting the difference to serve as the compensated sensing value of the target sensor.

In some embodiments, the step of recording different compensating values corresponding to the sensors into the look-up table includes keeping the sensors in a non-load state; sensing the sensors in the non-load state to obtain non-load sensing values of the sensors; taking the non-load sensing values as different compensating values corresponding to the sensors, and recording the compensating values into the look-up table.

In some other embodiments, the step of recording different compensating values corresponding to the sensors into the look-up table includes keeping the sensors in a non-load state; sensing the sensors in the non-load state to obtain non-load sensing values of the sensors; grouping the non-load sensing values into a plurality of groups according to magnitudes thereof, where each of the groups has a compensating value; and recording the compensating values corresponding to the non-load sensing values into the look-up table.

In another embodiment, the readout method for the sensor array further includes dynamically determining a gain value according to the switching operation; and gaining the sensing result according to the gain value to obtain the gained sensing value of the target sensor. The step of dynamically determining the gain value probably includes recording different gain values corresponding to the sensors into a look-up table; and getting the gain value of the target sensor from the look-up table according to the switching operation.

In another embodiment, the step of recording different gain values corresponding to the sensors into the look-up table includes keeping the sensors in a first load state (for example, a pressure of 500 g); sensing the sensors in the first load state to obtain first load sensing values of the sensors; keeping the sensors in a second load state (for example, a pressure of 200 g, or a non-load state); sensing the sensors in the second load state to obtain second load sensing values of the sensors; calculating slopes of load-sensing value characteristic curves of the sensors according to the first load sensing values and the second load sensing values; and taking the slopes as different gain values corresponding to the sensors and recording the gain values into the look-up table.

In another embodiment, the step of recording different gain values corresponding to the sensors into the look-up table includes keeping the sensors in a first load state; sensing the sensors in the first load state to obtain first load sensing values of the sensors; keeping the sensors in a second load state; sensing the sensors in the second load state to obtain second load sensing values of the sensors; calculating slopes of load-sensing value characteristic curves of the sensors according to the first load sensing values and the second load sensing values; grouping the slopes into a plurality of groups according to magnitudes thereof, where each of the groups has a gain value; and recording the gain values corresponding to the slopes into the look-up table.

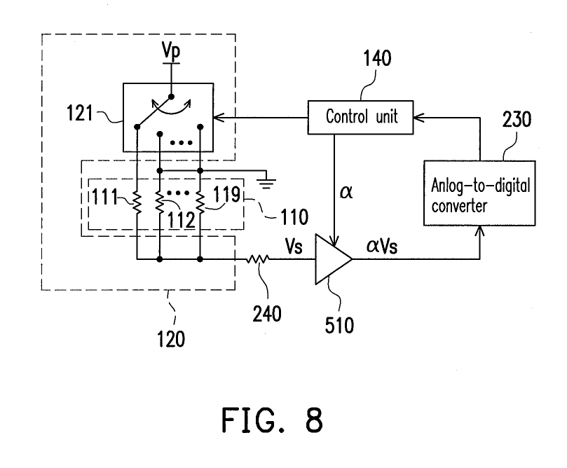

FIG. 8 is a functional block schematic diagram of a readout apparatus of a sensor array of FIG. 1 according to another embodiment of the disclosure. The embodiment of FIG. 8 can refer to the related descriptions of FIG. 1 to FIG. 6, and the same contents are not repeated. Different to the embodiment of FIG. 6, in the embodiment of FIG. 8, the offset compensating circuit 220 is omitted. The gain circuit 510 selectively senses a target sensor in the sensors 111-119 according to the switching operation of the switching circuit 120, and the gain circuit 510 gains the sensing result Vs according to the gain value α determined by the control unit 140 to output as the gained sensing value α×Vs of the target sensor. The gain circuit 510 transmits the gained sensing value α×Vs to the control unit 140 through the ADC 230.

A readout method for a sensor array is described below, which includes following steps. A switching operation is performed to select a target sensor from a plurality of sensors of the sensor array. A gain value is dynamically determined according to the switching operation. The target sensor in the sensors is selectively sensed according the switching operation to obtain a sensing result. The sensing result is gained according to the gain value to serve as a gained sensing value of the target sensor.

The aforementioned embodiments disclose a readout apparatus and a readout method of a variable resistance sensor array. The readout apparatus and the readout method can compensate different initial resistance of each of the pressure sensors in the non-load state, and compensate different response gain of each of the pressure sensors, so that the readout apparatus and the readout method of the disclosure can mitigate measurement error and a problem in array measurement uniformity, so as to avoid false operation of the system caused by poor device characteristic. The readout apparatus and the readout method disclosed in the embodiments of the disclosure may have following effects:
1. Influence on a system module caused by fabrication process variation of the pressure sensors or material error is reduced, so as to effectively improve performance of the pressure sensor array module.
2. A sensor error is modified through the readout apparatus, so as to improve a yield of the pressure sensors.
3. Integration complexity of a post system application product is reduced, so as to accelerate innovation and popularisation of the product.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A readout apparatus for a sensor array, comprising:
a switching circuit, coupled to the sensor array;
a control unit, coupled to the switching circuit, wherein the control unit controls the switching circuit to perform a switching operation for selecting a target sensor from a plurality of sensors of the sensor array, and the control unit dynamically determines a compensating value according the switching operation;
a gain circuit, selectively sensing the target sensor in the sensors according the switching operation of the switching circuit, and gaining a sensing result to output as a gained sensing value of the target sensor; and
an offset compensating circuit, coupled to the gain circuit for receiving the gained sensing value, and adjusting the gained sensing value according to the compensating value to output as a compensated sensing value of the target sensor.

2. The readout apparatus for the sensor array as claimed in claim 1, wherein the sensors are pressure sensors, the switching circuit performs the switching operation to switch a bias voltage to the target sensor, and the switching circuit couples a reference voltage lower than the bias voltage to other sensors in the sensors except the target sensor.

3. The readout apparatus for the sensor array as claimed in claim 2, wherein the reference voltage is a ground voltage or a system lowest voltage.

4. The readout apparatus for the sensor array as claimed in claim 1, further comprising:
an overload protection resistor, coupled in series between the target sensor and the gain circuit.

5. The readout apparatus for the sensor array as claimed in claim 4, wherein the overload protection resistor is a thermal resistor, and one of the overload protection resistor and the target sensor has a positive temperature coefficient, and another one has a negative temperature coefficient.

6. The readout apparatus for the sensor array as claimed in claim 4, further comprising:
a thermal resistor, connected in parallel to the overload protection resistor, wherein one of the thermal resistor and the target sensor has a positive temperature coefficient, and another one has a negative temperature coefficient.

7. The readout apparatus for the sensor array as claimed in claim 1, wherein the control unit dynamically determines a gain value according to the switching operation of the switching circuit, and the gain circuit gains the sensing result according to the gain value to obtain the gained sensing value of the target sensor.

8. The readout apparatus for the sensor array as claimed in claim 7, wherein the gain circuit comprises:
a first amplifier, having a non-inverting input terminal coupled to a reference voltage, and an inverting input terminal selectively coupled to the target sensor according to the switching operation of the switching circuit; and
a first variable resistance unit, having a first end and a second end respectively coupled to the inverting input terminal and an output terminal of the first amplifier, wherein a resistance of the first variable resistance unit is varied according to the switching operation of the switching circuit.

9. The readout apparatus for the sensor array as claimed in claim 8, wherein the first variable resistance unit comprises:
a plurality of first resistors, having first ends commonly coupled to the output terminal of the first amplifier, wherein resistances of the first resistors are different; and
a first switch, selectively coupling the inverting input terminal of the first amplifier to a second end of one of the first resistors according to the switching operation of the switching circuit.

10. The readout apparatus for the sensor array as claimed in claim 8, wherein the gain circuit further comprises:
a second amplifier, having a non-inverting terminal coupled to the reference voltage, and an output terminal providing the gained sensing value to the offset compensating circuit;
a second resistor, having a first end and a second end respectively coupled to the output terminal of the first amplifier and an inverting input terminal of the second amplifier; and
a third resistor, having a first end and a second end respectively coupled to the inverting input terminal of the second amplifier and the output terminal of the second amplifier.

11. The readout apparatus for the sensor array as claimed in claim 7, wherein the control unit has a look-up table for recording different gain values corresponding to the sensors, and the control unit gets the gain value of the target sensor from the look-up table according to the switching operation of the switching circuit.

12. The readout apparatus for the sensor array as claimed in claim 1, wherein the control unit has a look-up table for recording different compensating values corresponding to the sensors, and the control unit gets the compensating value of the target sensor from the look-up table according to the switching operation of the switching circuit.

13. The readout apparatus for the sensor array as claimed in claim 1, wherein the offset compensating circuit is an error amplifier, an inverting input terminal of the error amplifier receives the compensating value, a non-inverting input terminal of the error amplifier is coupled to the gain circuit for receiving the gained sensing value, and an output terminal of the error amplifier outputs the compensated sensing value.

14. The readout apparatus for the sensor array as claimed in claim 1, wherein the offset compensating circuit is a subtracter, and the subtracter receives and calculates a difference between the gained sensing value and the compensating value, and outputs the difference to serve as the compensated sensing value of the target sensor.

15. The readout apparatus for the sensor array as claimed in claim 1, wherein the offset compensating circuit comprises:
a third amplifier, having a non-inverting input terminal coupled to the gain circuit for receiving the gained sensing value;
a fourth amplifier, having a non-inverting input terminal receiving the compensating value;
a fourth resistor, having a first end and a second end respectively coupled to an inverting input terminal of the third amplifier and an inverting input terminal of the fourth amplifier;
a fifth resistor, having a first end and a second end respectively coupled to the inverting input terminal and an output terminal of the third amplifier;
a sixth resistor, having a first end and a second end respectively coupled to the inverting input terminal and an output terminal of the fourth amplifier;
a seventh resistor, having a first end coupled to the output terminal of the third amplifier;
an eighth resistor, having a first end coupled to the output terminal of the fourth amplifier;
a fifth amplifier, having a non-inverting input terminal coupled to a second end of the seventh resistor, an inverting input terminal coupled to a second end of the eighth resistor, and an output terminal outputting the compensated sensing value;
a ninth resistor, having a first end and a second end respectively coupled to the inverting input terminal and the output terminal of the fifth amplifier; and
a tenth resistor, having a first end coupled to the non-inverting input terminal of the fifth amplifier, and a second end coupled to a reference voltage.

16. The readout apparatus for the sensor array as claimed in claim 1, further comprising:
a digital-to-analog converter, dynamically outputting the compensating value to the offset compensating circuit under control of the control unit.

17. The readout apparatus for the sensor array as claimed in claim 1, further comprising:
a second variable resistance unit, having a first end coupled to a bias voltage, wherein a resistance of the second variable resistance unit is varied under control of the control unit;
an eleventh resistor, having a first end coupled to a second end of the second variable resistance unit, and a second end coupled to a reference voltage; and
a sixth amplifier, having a non-inverting input terminal coupled to the second end of the second variable resistance unit, an inverting input terminal coupled to an output terminal of the sixth amplifier, and the output terminal outputting the compensating value to the offset compensating circuit.

18. A readout method for a sensor array, comprising:
performing a switching operation to select a target sensor from a plurality of sensors of the sensor array;
dynamically determining a compensating value according to the switching operation;
selectively sensing the target sensor in the sensors according the switching operation, and gaining a sensing result to serve as a gained sensing value of the target sensor; and
adjusting the gained sensing value according to the compensating value to serve as a compensated sensing value of the target sensor.

19. The readout method for the sensor array as claimed in claim 18, wherein the sensors are pressure sensors, the switching operation switches a bias voltage to the target sensor, and the switching operation couples a reference voltage lower than the bias voltage to other sensors in the sensors except the target sensor.

20. The readout method for the sensor array as claimed in claim 19, wherein the reference voltage is a ground voltage or a system lowest voltage.

21. The readout method for the sensor array as claimed in claim 18, further comprising:
dynamically determining a gain value according to the switching operation; and
gaining the sensing result according to the gain value to obtain the gained sensing value of the target sensor.

22. The readout method for the sensor array as claimed in claim 21, wherein the step of dynamically determining the gain value comprises:
recording different gain values corresponding to the sensors into a look-up table; and
getting the gain value of the target sensor from the look-up table according to the switching operation.

23. The readout method for the sensor array as claimed in claim 22, wherein the step of recording different gain values corresponding to the sensors into the look-up table comprises:
keeping the sensors in a first load state;
sensing the sensors in the first load state to obtain first load sensing values of the sensors;
keeping the sensors in a second load state;
sensing the sensors in the second load state to obtain second load sensing values of the sensors;
calculating slopes of load-sensing value characteristic curves of the sensors according to the first load sensing values and the second load sensing values; and
taking the slopes as different gain values corresponding to the sensors, and recording the gain values into the look-up table.

24. The readout method for the sensor array as claimed in claim 22, wherein the step of recording different gain values corresponding to the sensors into the look-up table comprises:
keeping the sensors in a first load state;
sensing the sensors in the first load state to obtain first load sensing values of the sensors;
keeping the sensors in a second load state;
sensing the sensors in the second load state to obtain second load sensing values of the sensors;
calculating slopes of load-sensing value characteristic curves of the sensors according to the first load sensing values and the second load sensing values;
grouping the slopes into a plurality of groups according to magnitudes thereof, wherein each of the groups has a gain value; and
recording the gain values corresponding to the slopes into the look-up table.

25. The readout method for the sensor array as claimed in claim 18, wherein the step of dynamically determining the compensating value comprises:
recording different compensating values corresponding to the sensors into a look-up table; and
getting the compensating value of the target sensor from the look-up table according to the switching operation.

26. The readout method for the sensor array as claimed in claim 25, wherein the step of recording different compensating values corresponding to the sensors into the look-up table comprises:
keeping the sensors in a non-load state;
sensing the sensors in the non-load state to obtain non-load sensing values of the sensors;
taking the non-load sensing values as different compensating values corresponding to the sensors, and recording the compensating values into the look-up table.

27. The readout method for the sensor array as claimed in claim 25, wherein the step of recording different compensating values corresponding to the sensors into the look-up table comprises:
keeping the sensors in a non-load state;
sensing the sensors in the non-load state to obtain non-load sensing values of the sensors;
grouping the non-load sensing values into a plurality of groups according to magnitudes thereof, wherein each of the groups has a compensating value; and
recording the compensating values corresponding to the non-load sensing values into the look-up table.

28. The readout method for the sensor array as claimed in claim 18, wherein the step of adjusting the gained sensing value comprises:
calculating a difference between the gained sensing value and the compensating value; and
outputting the difference to serve as the compensated sensing value of the target sensor.

29. A readout apparatus for a sensor array, comprising:
a switching circuit, coupled to the sensor array;
a control unit, coupled to the switching circuit, wherein the control unit controls the switching circuit to perform a switching operation for selecting a target sensor from a plurality of sensors of the sensor array, and the control unit dynamically determines a gain value according the switching operation; and
a gain circuit, selectively sensing the target sensor in the sensors according the switching operation of the switching circuit, and gaining a sensing result according to the gain value to output as a gained sensing value of the target sensor.

30. The readout apparatus for the sensor array as claimed in claim 29, wherein the sensors are pressure sensors, the switching circuit performs the switching operation to switch a bias voltage to the target sensor, and the switching circuit couples a reference voltage lower than the bias voltage to other sensors in the sensors except the target sensor.

31. The readout apparatus for the sensor array as claimed in claim 30, wherein the reference voltage is a ground voltage or a system lowest voltage.

32. The readout apparatus for the sensor array as claimed in claim 29, further comprising:
an overload protection resistor, coupled in series between the target sensor and the gain circuit.

33. The readout apparatus for the sensor array as claimed in claim 32, wherein the overload protection resistor is a thermal resistor, and one of the overload protection resistor and the target sensor has a positive temperature coefficient, and another one has a negative temperature coefficient.

34. The readout apparatus for the sensor array as claimed in claim 32, further comprising:
a thermal resistor, connected in parallel to the overload protection resistor, wherein one of the thermal resistor and the target sensor has a positive temperature coefficient, and another one has a negative temperature coefficient.

35. The readout apparatus for the sensor array as claimed in claim 29, wherein the gain circuit comprises:
a first amplifier, having a non-inverting input terminal coupled to a reference voltage, and an inverting input terminal selectively coupled to the target sensor according to the switching operation of the switching circuit; and
a first variable resistance unit, having a first end and a second end respectively coupled to the inverting input terminal and an output terminal of the first amplifier, wherein a resistance of the first variable resistance unit is varied according to the switching operation of the switching circuit.

36. The readout apparatus for the sensor array as claimed in claim 35, wherein the first variable resistance unit comprises:
a plurality of first resistors, having first ends commonly coupled to the output terminal of the first amplifier, wherein resistances of the first resistors are different; and
a first switch, selectively coupling the inverting input terminal of the first amplifier to a second end of one of the first resistors according to the switching operation of the switching circuit.

37. The readout apparatus for the sensor array as claimed in claim 35, wherein the gain circuit further comprises:
a second amplifier, having a non-inverting terminal coupled to the reference voltage, and an output terminal providing the gained sensing value;
a second resistor, having a first end and a second end respectively coupled to the output terminal of the first amplifier and an inverting input terminal of the second amplifier; and
a third resistor, having a first end and a second end respectively coupled to the inverting input terminal of the second amplifier and the output terminal of the second amplifier.

38. The readout apparatus for the sensor array as claimed in claim 29, wherein the control unit has a look-up table for recording different gain values corresponding to the sensors, and the control unit gets the gain value of the target sensor from the look-up table according to the switching operation of the switching circuit.

39. A readout method for a sensor array, comprising:
performing a switching operation to select a target sensor from a plurality of sensors of the sensor array;
dynamically determining a gain value according to the switching operation;
selectively sensing the target sensor in the sensors according the switching operation to obtain a sensing result; and
gaining the sensing result according to the gain value to serve as a gained sensing value of the target sensor.

40. The readout method for the sensor array as claimed in claim 39, wherein the sensors are pressure sensors, the switching operation switches a bias voltage to the target sensor, and the switching operation couples a reference voltage lower than the bias voltage to other sensors in the sensors except the target sensor.

41. The readout method for the sensor array as claimed in claim 40, wherein the reference voltage is a ground voltage or a system lowest voltage.

42. The readout method for the sensor array as claimed in claim 39, wherein the step of dynamically determining the gain value comprises:
recording different gain values corresponding to the sensors into a look-up table; and
getting the gain value of the target sensor from the look-up table according to the switching operation.

43. The readout method for the sensor array as claimed in claim 42, wherein the step of recording different gain values corresponding to the sensors into the look-up table comprises:
keeping the sensors in a first load state;
sensing the sensors in the first load state to obtain first load sensing values of the sensors;
keeping the sensors in a second load state;
sensing the sensors in the second load state to obtain second load sensing values of the sensors;
calculating slopes of load-sensing value characteristic curves of the sensors according to the first load sensing values and the second load sensing values; and
taking the slopes as different gain values corresponding to the sensors, and recording the gain values into the look-up table.

44. The readout method for the sensor array as claimed in claim 42, wherein the step of recording different gain values corresponding to the sensors into the look-up table comprises:
keeping the sensors in a first load state;
sensing the sensors in the first load state to obtain first load sensing values of the sensors;
keeping the sensors in a second load state;
sensing the sensors in the second load state to obtain second load sensing values of the sensors;
calculating slopes of load-sensing value characteristic curves of the sensors according to the first load sensing values and the second load sensing values;
grouping the slopes into a plurality of groups according to magnitudes thereof, wherein each of the groups has a gain value; and
recording the gain values corresponding to the slopes into the look-up table.
